(19) United States
(12) Patent Application Publication
(10) Pub. No.: US 2011/0241077 A1
(43) Pub. Date: Oct. 6, 2011

(54) INTEGRATED CIRCUIT 3D MEMORY ARRAY AND MANUFACTURING METHOD

(75) Inventor: HSIANG-LAN LUNG, Dobbs Ferry, NY (US)

(73) Assignee: Macronix International Co., Ltd., Hsinchu (TW)

(21) Appl. No.: 12/755,325

(22) Filed: Apr. 6, 2010

(51) Int. Cl. H01L 23/48; H01L 21/70

(52) U.S. Cl. 257/208; 438/131; 257/E23.01; 257/E21.532

(57) ABSTRACT

A 3D memory device is based on an array of conductive pillars and a plurality of patterned conductor planes including left side and right side conductors adjacent the conductive pillars at left side and right side interface regions. Memory elements in the left side and right side interface regions comprise a programmable element and a rectifier. The conductive pillars can be selected using two-dimensional decoding, and the left side and right side conductors in the plurality of planes can be selected using decoding on a third dimension, combined with left and right side selection.

### BACKGROUND OF THE INVENTION

1. Field of the Invention

The present invention relates to high density memory devices, and particularly to memory devices in which multiple planes of memory cells are arranged to provide a three-dimensional 3D array.

2. Description of Related Art

As critical dimensions of devices in integrated circuits shrink to the limits of common memory cell technologies, designers have been looking to techniques for stacking multiple planes of memory cells to achieve greater storage capacity, and to achieve lower costs per bit. For example, cross-point array techniques have been applied for anti-fuse memory in Johnson et al., “512-Mb PROM With a Three-Dimensional Array of Diode/Anti-fuse Memory Cells” IEEE J. of Solid-State Circuits, vol. 38, no. 11 Nov. 2003. In the design described in Johnson et al., multiple layers of word lines and bit lines are provided, with memory elements at the cross-points. The memory elements comprise a p+ polysilicon anode connected to a word line, and an n-polysilicon cathode connected to a bit line, with the anode and cathode separated by anti-fuse material.

In the processes described in Johnson et al., there are several critical lithography steps for each memory layer. Thus, the number of critical lithography steps needed to manufacture the device is multiplied by the number of layers that are implemented. Critical lithography steps are expensive, and so it is desirable to minimize them in manufacturing integrated circuits. So, although the benefits of higher density are achieved using 3D arrays, the higher manufacturing costs limit the use of the technology.

One technology for 3D anti-fuse memory is described in co-pending U.S. patent application entitled INTEGRATED CIRCUIT 3D MEMORY ARRAY AND MANUFACTURING METHOD, application Ser. No. 12/430,290, filed 27 Apr. 2009, which is incorporated by reference as if fully set forth herein.

It is desirable to provide a structure for three-dimensional integrated circuit memory with high density and low manufacturing cost, including reliable, very small memory elements.

### SUMMARY OF THE INVENTION

A memory device on an integrated circuit is described that includes a 3D memory array of 2-cell unit structures including programmable resistance elements such as anti-fuses. The 3D array includes a plurality of patterned conductor layers separated from each other by insulating layers. An array of access devices is included on the integrated circuit arranged to provide access to individual conductive pillars which extend into the 3D array. The patterned conductive layers include left side and right side conductors adjacent the conductive pillars. This defines the left side and right side interface region between the conductive pillars and adjacent left side and right side conductors. Memory elements are provided in the left side and right side interface regions, each of which comprises a programmable element and a rectifier.

A device as described herein can include row decoder circuits and column decoder circuits coupled to the array of access devices, and arranged to select an individual conductive pillar in the array of conductive pillars. Also, left and right plane decoding circuits are coupled to the left side and right side conductors in the plurality of patterned conductor layers. Decoding circuits are arranged to forward bias the rectifier in a selected cell, in a left side or right side interface region in a selected patterned conductor layer, and to reverse bias the rectifier to an unselected cell.

In a structure described herein, the conductive pillars in the array comprise a semiconductor material having a first conductivity type in electrical communication with a corresponding access device. Also, the left side and right side conductors comprise a semiconductor material having a second conductivity type, so that the rectifier in each of the memory elements comprises a p-n junction.

The left side and right side conductors in each layer have landing areas that are not overlaid by any of the left side and right side conductors in overlying patterned conductor layers. Conductive lines such as metal plugs extend through vias to the plurality of patterned conductor layers and contact the landing areas. Left side and right side connectors in a patterned metallization layer for example, and over the plurality of patterned conductor layers, connect with the conductive lines in the vias and provide for connection to the decoding circuitry.

A method for manufacturing a memory device is described as well. The plurality of patterned conductor layers can be formed by first forming a plurality of blanket layers of conductive material with blanket layers of insulating material between the blanket layers of conductive material to form a stack. Then, the stack is etched to define the left side and right side conductors, such as by forming trenches in the stack. A layer of the memory material is deposited on the side walls of the trenches, and then the trenches are filled with a conductive material, such as a doped semiconductor. Next, the conductive material is patterned within the trench to form the conductive pillars. Insulating material is then filled in between the pillars.

A memory cell is programmed by applying voltage bias between the conductive pillar and a selected left side or right side conductor line in the desired plane to break down the anti-fuse material, or otherwise program a programmable resistance memory element, in the interface region. A rectifier, established by the p-n junction in the interface region or otherwise, provides isolation between memory cells on different layers within the pillar.

Other aspects and advantages of the present invention can be seen on review of the drawings, the detailed description and the claims, which follow.

### BRIEF DESCRIPTION OF THE DRAWINGS

FIG. 1 is a schematic illustration showing an X-Z slice view of a 3D anti-fuse memory structure, as described herein.

FIG. 2 is a schematic illustration showing an X-Y level view of a 3D anti-fuse memory structure, as described herein.

FIG. 3 shows the structure of a two-cell unit structure along with the symbol for the unit cell utilized in FIG. 1 and FIG. 2 of the 3D anti-fuse memory structure.

FIG. 4 is a perspective drawing of a portion of a 3D anti-fuse memory structure described herein.

FIGS. 5-11 show a sequence of stages of a manufacturing process for making the 3D memory structure described herein.

FIG. 12 is a layout view in the X-Y plane of a level of the 3D anti-fuse memory structure described herein.

FIG. 13 and FIGS. 14A-14C illustrate a 3D interconnect structure for coupling the word line levels to decoding circuitry.

FIG. 15 illustrates implementation of a representative pillar access device array in a substrate.

FIG. 16 is a simplified block diagram of an integrated circuit including a 3D anti-fuse, two-cell unit structure memory array.

### DETAILED DESCRIPTION

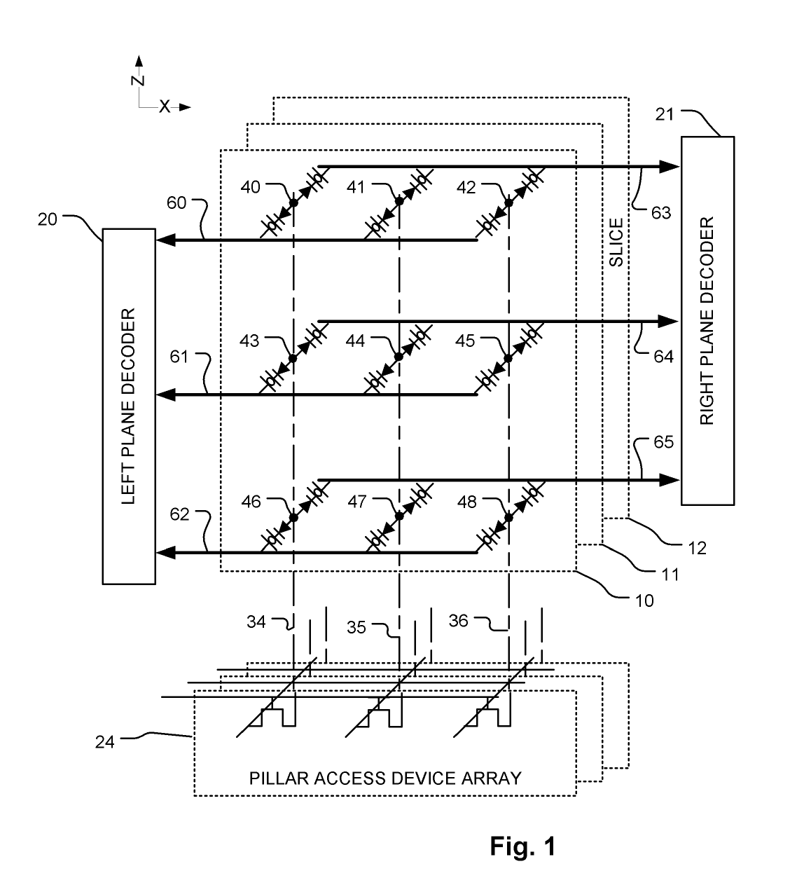

A detailed description of embodiments of the present invention is provided with reference to the FIGS. 1-16.

FIG. 1 is a schematic diagram of a 3D memory device, showing “slices” 10, 11, 12 which lie in X-Z planes of the 3D structure. In the illustrated schematic, there are nine two-cell unit structures 40-48, each unit structure having two memory cells having separate programmable elements and left and right gates. Embodiments of the 3D memory device can include many two-cell unit structures per slice. The device includes an array of cells arranged for left and right decoding, using a left plane decoder 20, right plane decoder 21, and pillar access device array 24. The semiconductor pillars of the two-cell unit structures in a Z-direction column (e.g. 40, 43, 46) are coupled via a semiconductor pillar (e.g. 34) to an access device in a pillar access device array 24, implemented for example in the integrated circuit substrate beneath the structure. Likewise, the pillars for the two-cell unit structures 41, 44, 47 are coupled via a semiconductor pillar 35 to a corresponding access device in the pillar access device array 24. The pillars for the two-cell unit structures 42, 45, 48 are coupled via the semiconductor pillar 36 to the pillar access device array 24.

The left side word line conductors (e.g. 60) on the two-cell unit structures in a particular level (e.g. structures 40, 41, 42) in all of the slices 10, 11, 12 are coupled to a driver selected by left plane decoder 20. Likewise, the right side word line conductors (e.g. 63) on the unit structures in a particular level (e.g. 40, 41, 42) in all of the slices 10, 11, 12 are coupled to a driver selected by right plane decoder 21. The left side word line conductor 61 and right side word line conductor 64 on the level including unit structures 43, 44, 45 are coupled to the left plane decoder 20 and to the right plane decoder 21, respectively. The left side word line conductor 62 and right side word line conductor 65 on the level including unit structures 46, 47, 48 are coupled to the left plane decoder 20 and to the right plane decoder 21, respectively.

The two-cell unit structures 40-48 include a programmable element and a rectifier for each cell, as indicated in schematic form in FIG. 1. More details of the two-cell unit structure are provided below.

As can be seen, a current path for reading an individual cell (e.g. one of the two cells in unit structure 43) is established by applying a voltage to forward bias the rectifier between the corresponding pillar (e.g. pillar 34), and a selected one of the left side and right side conductors on a selected plane (e.g. one of conductors 61 and 64), while reverse biasing or disconnecting rectifiers in other cells in the array.

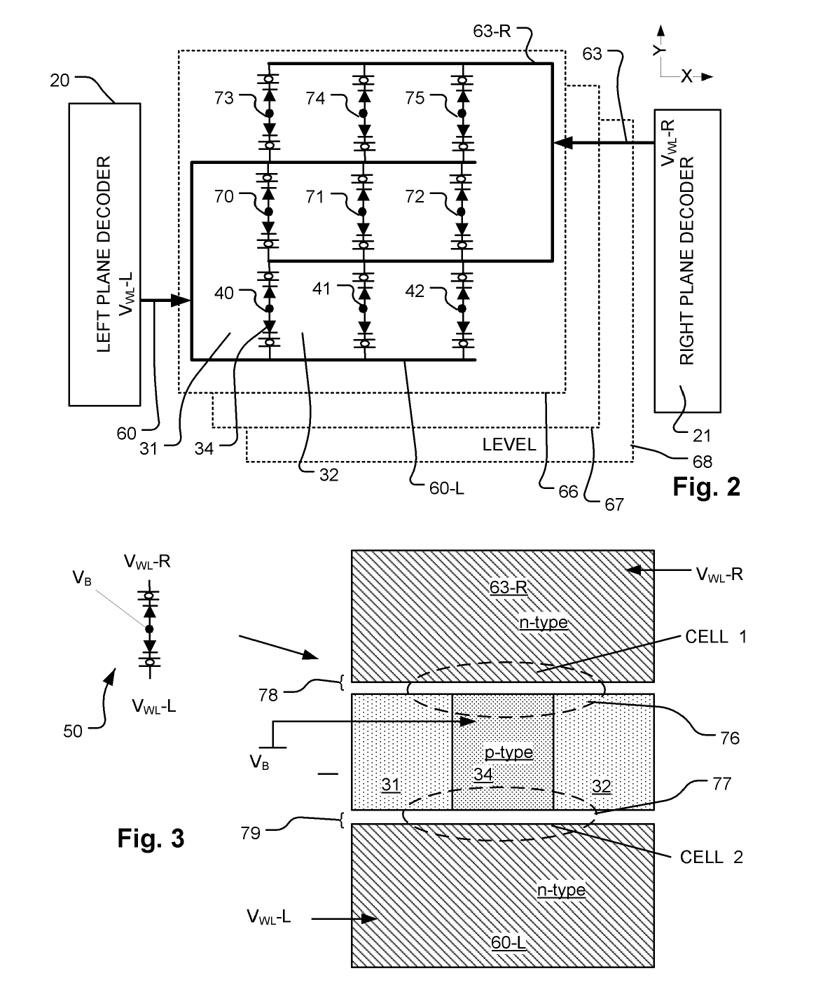

FIG. 2 is a schematic diagram of a 3D memory device, showing “levels” 66, 67, 68, which lie in X-Y planes of the 3D structure. The left plane decoder 20 and right plane decoder 21 are illustrated in the figure. Each level in the schematic includes nine two-cell unit structures. Embodiments can include many cells per level. The front row of unit structures in level 66 in the schematic includes structures 40, 41 and 42, corresponding to the top row in the slice shown in FIG. 1. The balance of the two-cell unit structures 70-75 shows 3-by-3, X-Y arrangement of unit structures on the level, although the array can be much larger, including for example 1000×1000 two-cell units on each plane, or more. As shown in FIG. 2, the left word line element 60 is arranged to connect to the left side conductors between alternating pairs of rows using a forked word line element 60-L. Likewise, the right word line element 63 is interleaved with the left word line element 60, and arranged to connect to the right side conductors between the other alternating pairs of rows using forked word line element 63-R. As described below, the left and right side conductors may be separated from one another in each plane, and connected by vias to overlying connectors (rather than forked and connected together in the plane as shown).

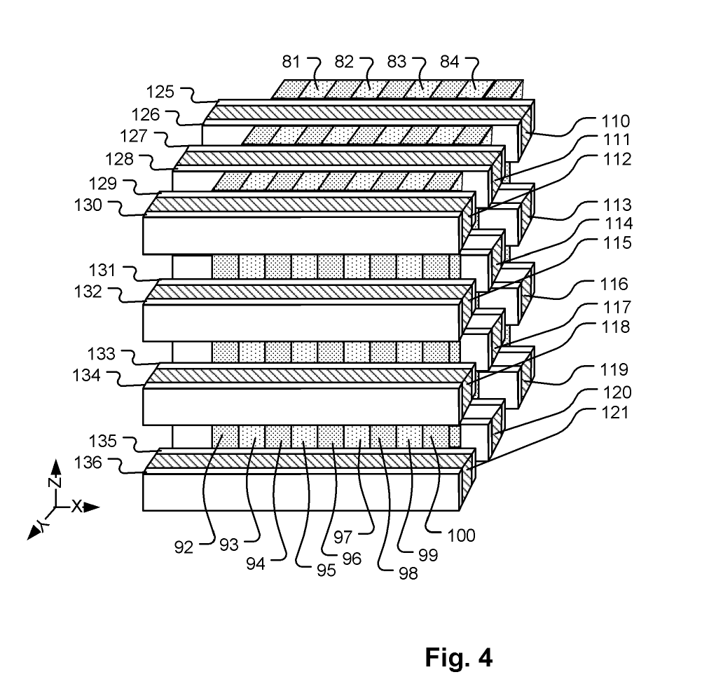

The two-cell unit structure is shown in FIG. 3. The symbol 50 which is utilized in FIG. 1 and FIG. 2 representing the unit structure can be represented by the structure shown, including left side conductor 60-L, right side conductor 63-R, and the semiconductor pillar 34. Dielectric insulators 31 and 32 separate the pillars. The layers 78, 79 of programmable material lie on opposing sides of the semiconductor pillar 34 and between respective surfaces on opposing sides of the semiconductor pillar 34 and the corresponding left side and right side conductors, 60-L or 63-R. Thus, two memory cells are provided by this unit structure, including CELL 1 and CELL 2 as labeled in the drawing, each cell including a programmable element and a rectifier.

The conductor lines 60-L and 63-R for this example comprise a relatively highly doped, n+ polysilicon, while the semiconductor pillar 34 comprises a relatively more lightly doped, p-type polysilicon. This results in formation of a p-n junction rectifier for the memory cell in the interface region. Other semiconductors to form the p-n junction can be used, including metal oxides and others.

The rectifier implemented by the p-n junction between the conductor line and the polysilicon in the pillar can be replaced by other rectifiers. For example, a rectifier based on a solid electrolyte like for example germanium silicide, or other suitable material, could be used to provide a rectifier. See U.S. Pat. No. 7,382,647 by Gopalakrishnan for other representative solid electrolyte materials.

Bias voltages applied to the unit structures include the right word line voltage V_{WL-}-R, the left word line voltage V_{WL}-L, and the pillar voltage V_{B}.

The memory cells are formed in the interface regions 76, 77, and include semiconductor pillar 34, which can include a conductive core, and a layer 78 of anti-fuse material. In the native state, a layer 78 of anti-fuse material, which can be a silicon dioxide, silicon oxynitride or other silicon oxide, for example having a thickness on the order of 5 to 10 nanometers, has a high resistance. Other anti-fuse materials may be used, such as silicon nitride, aluminum oxide, tantalum oxide, magnesium oxide and so on.

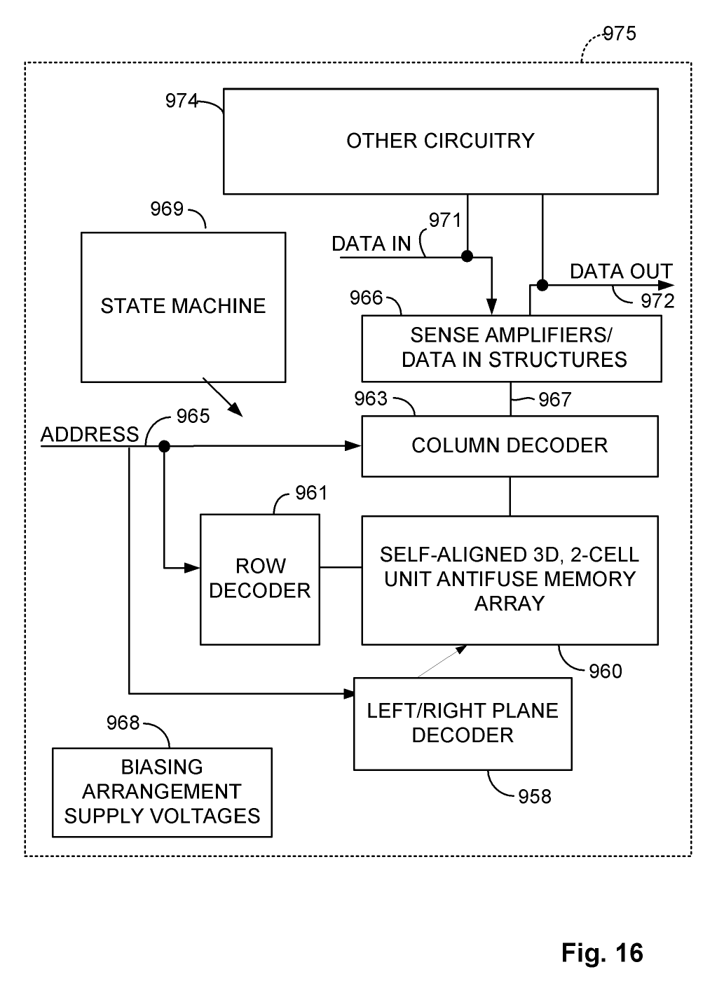

After programming, the anti-fuse material breaks down so that the active area within the anti-fuse material assumes a low resistance state. In a typical embodiment, using a silicon oxide anti-fuse, a programming pulse may comprise a 5 to 7 volt pulse having a pulse width of about one microsecond, applied under control of on-chip control circuits as described below with reference to FIG. 16. A read pulse may comprise a 1 to 2 volt pulse having a pulse width that depends on the configuration, applied under control of on-chip control circuits as described below with reference to FIG. 16. The read pulse can be much shorter than the programming pulse.

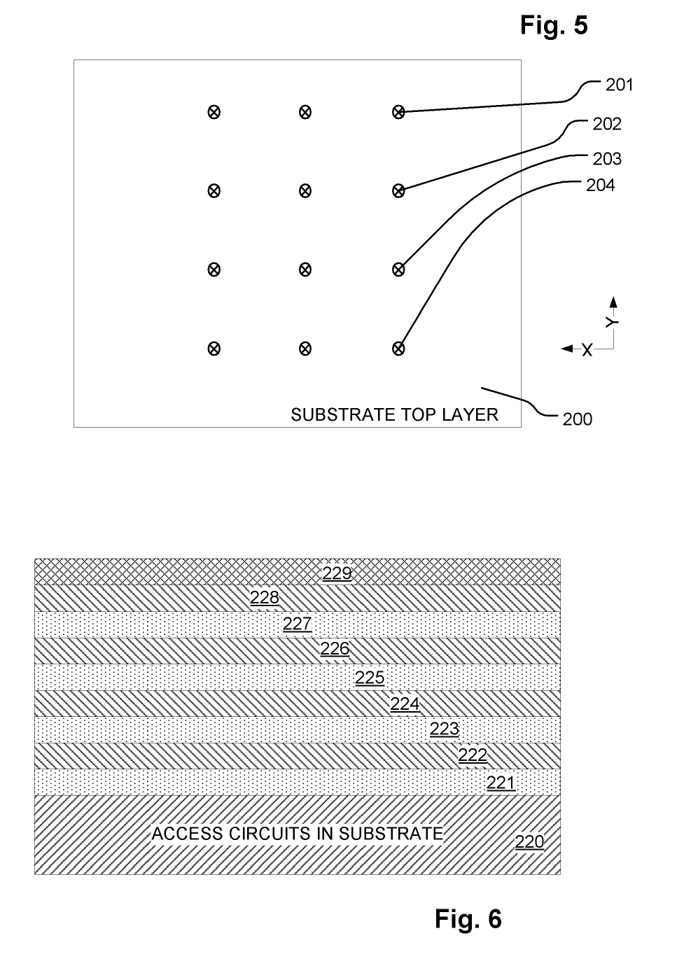

FIG. 4 shows a portion of a 3D structure including an array of memory cells as described with reference to FIGS. 1-3. Four patterned conductor layers are illustrated, where a top level includes patterned conductors 110-112 extending in the X-direction, a next lower level includes patterned conductors 113-115, a next level includes patterned conductors 116-118, and a bottom level includes patterned conductors 119-121. Programmable elements 125-130 are formed on the opposing sides of the patterned conductors 110-112 on the top level. Programmable elements 131-132 are formed on opposing sides of patterned conductor 115, programmable elements 133-134 are formed on the opposing side of patterned conductor 118 and programmable elements 135-136 are formed on opposing sides of patterned conductor 121. Similar programmable elements are formed on the sides of the other patterned conductors in the structure as well. The structure includes an array of semiconductor pillars, including pillars 81-84 in the back of the structure shown, and pillars 93, 95, 97 and 99 on the front of the structure shown. Between and on opposing sides of the semiconductor pillars, insulating pillars are formed. Thus, insulating pillars 92, 94, 96, 98 and 100 are shown on opposing sides of the semiconductor pillars 93, 95, 97 and 99.

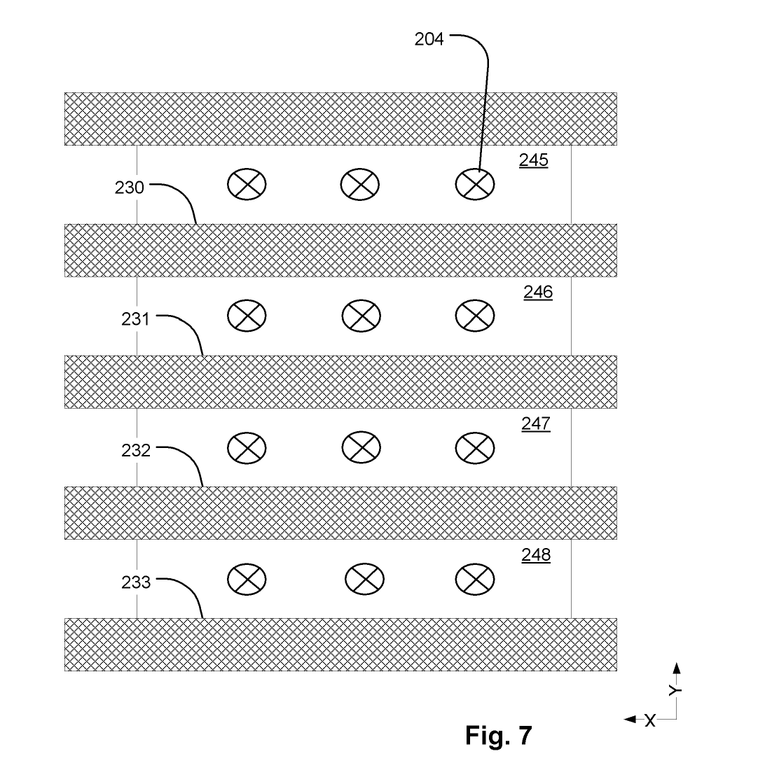

FIGS. 5-11 illustrate stages in a process for manufacturing the structure discussed above. In FIG. 5, a surface 200 of an integrated circuit substrate is illustrated with an array of contacts for connection to the 3D structure. The array of contacts includes contacts (e.g. 201-204) which are coupled to individual access devices, and adapted for connection to the semiconductor pillars in the 3D structure. The individual access devices can be formed in the substrate, and may include for example MOS transistors having gates coupled to word lines arranged in the X-direction, sources coupled to the source lines arranged in the Y-direction, and drains connected to the contacts (e.g. 201-204). The individual access devices are selected by biasing the word lines and source lines as appropriate for the particular operation. In some implementations, the access devices can comprise vertical, surrounding gate transistors, in which an upper source/drain terminal is coupled to the semiconductor pillar. In this case, the access array includes a surrounding gate word line, and an source line or bit line contacting or acting as the lower source/drain terminal in the vertical transistor.

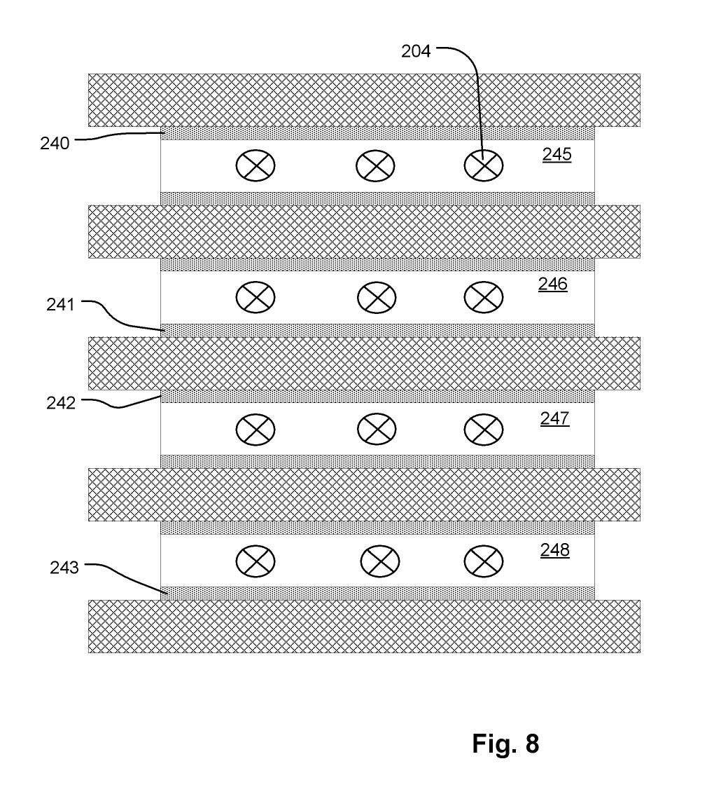

FIG. 6 is a side cross-section showing a multilayer stack of materials at a first stage in the manufacturing process, after forming alternating layers 221, 223, 225, 227 of insulating material, such as silicon dioxide or silicon nitride, and layers 222, 224, 226, 228 of conductor material, such as n+-polysilicon, other doped semiconductor, metals or others, on top of the substrate 220. In a representative structure, the thicknesses of the alternating layers of insulating material can be about 50 nanometers, and the thicknesses of the alternating layers of conductor material can be about 50 nanometers. Over the top of the alternating layers, a layer 229 of hard mask material, such as silicon nitride, can be formed.

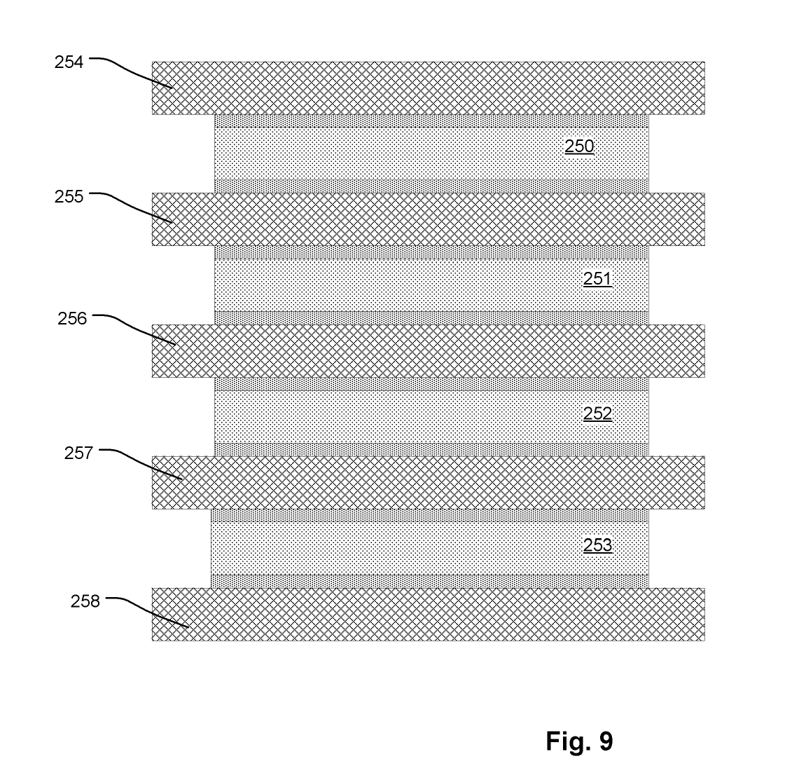

FIG. 7 is a layout view from a perspective over layer 229 showing the results using a first lithographic process to define a pattern for the trenches, and a patterned etch of the stack to form trenches 245-248 through the multilayer stack of materials shown in FIG. 6, exposing contacts, such as contact 204, coupled to individual access devices in the pillar access circuits. Anisotropic reactive ion etching techniques can be used to etch through the polysilicon and silicon oxide or silicon nitride layers, with a high aspect ratio. The trenches have sidewalls 230-233 on which the layers of conductor material are exposed at each level of the structure. The widths of the trenches 245-248 in a representative structure can be about 70 nanometers.

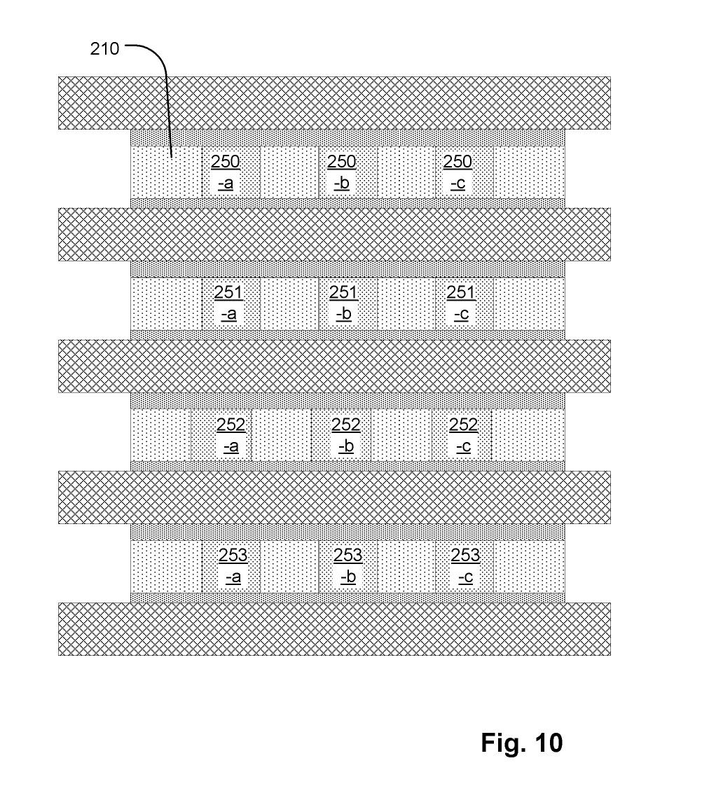

FIG. 8 shows a later stage in the process after deposition of a layer of anti-fuse material (240-243) over and on the sidewalls of the trenches (245-248) contacting the layers of conductor material. After deposition of the anti-fuse material, the process can include depositing a thin protective layer, such as p-type polysilicon over the anti-fuse material, and etching the resulting formation using an anisotropic process to remove the anti-fuse material (240-243) from the bottom of the trenches, 245-248, and exposing the contacts (e.g. 204).

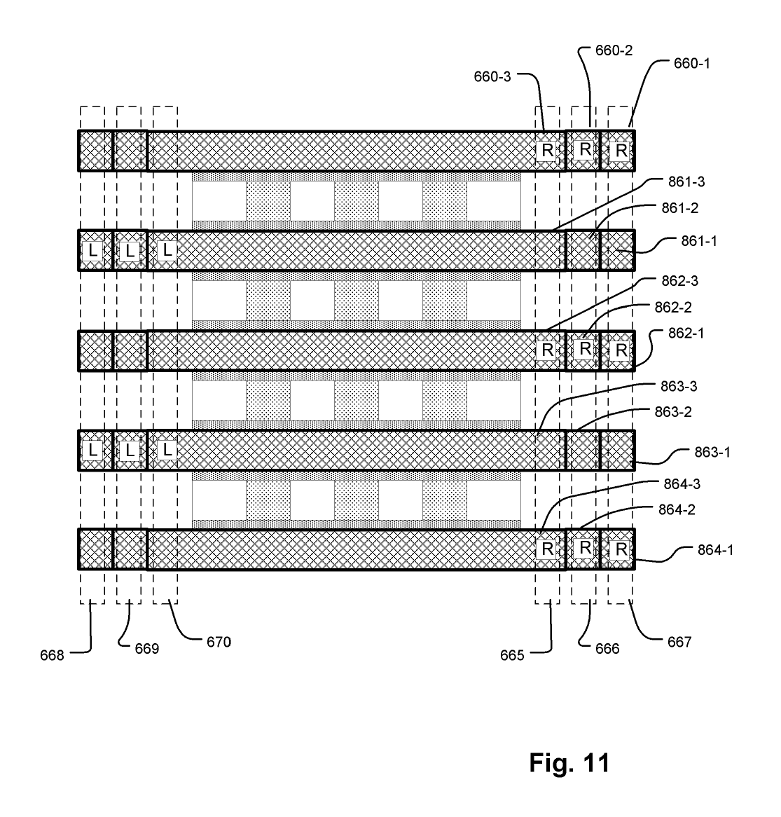

FIG. 9 shows a next stage in the process after filling the trenches with the material to be used for the conductive pillars, such as p-type polysilicon, to form filled trenches 250-253, between patterned conductors 254-258. In alternative structures, the trenches can be first lined using a doped semiconductor, and then filled using a metal, to improve conductivity of the structure, providing a rectifier in the interface region.

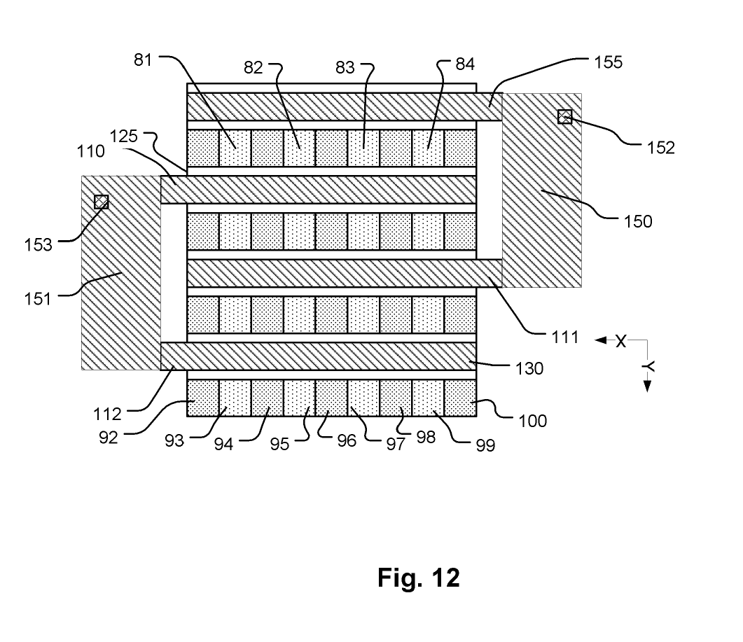

FIG. 10 shows the result of using a second lithographic process to define a pattern for the conductive pillars. A patterned etch of the filled trenches is applied using an anisotropic etch process that is selective for the material of the conductive pillars, to define the conductive pillars (250-a, 250-b, 250-c, 251-a, 251-b, 251-c, 252-a, 252-b, 252-c, 253-a, 253-b, 253-c) in contact with the contacts, including contact 204 (not shown), to the underlying individual access devices, and to create vertical openings between the conductive pillars. Next, dielectric insulating material, such as silicon dioxide, is filled in between the pillars to form insulator columns (e.g. insulator 210) between the pillars.

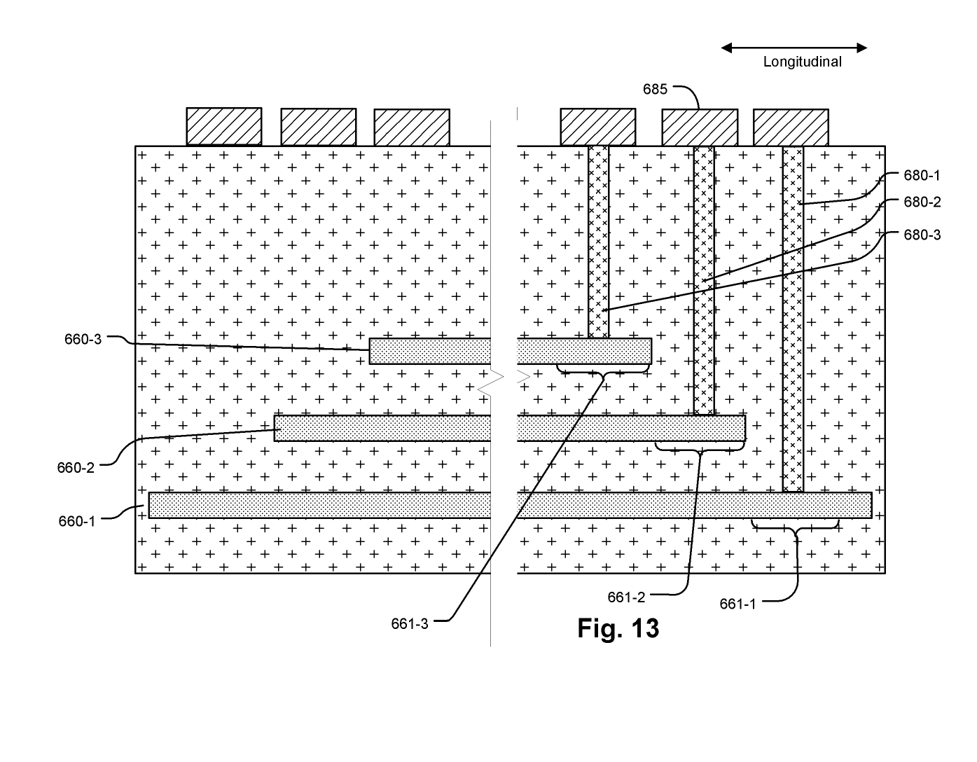

FIG. 11 illustrates a top view of a configuration for making contact to the left side and right side conductor lines in the plurality of planes. The left side conductors 861-1, 861-2, 861-3 and 863-1, 863-2, 863-3 and right side conductors 660-1, 660-2, 660-3, 862-1, 862-2, 862-3 and 864-1, 864-2, 864-3 in each layer have landing areas (labeled “L” or “R”) arranged in a stair-step pattern (or other pattern) so that the landing areas in each level are not overlaid by any of the left side and right side conductors in overlying patterned conductor layers. Contact plugs or other conductive lines (not shown) extend through the plurality of conductor layers and contact the landing areas. An overlying patterned connection layer includes left side connectors 668, 669, 670 and right side connectors 665, 666, 667 over the plurality of patterned conductor layers and in contact with the conductive lines contacting the landing areas of left and right side conductors. The left side and right side connectors are routed to left and right plane decoding circuits (not shown).

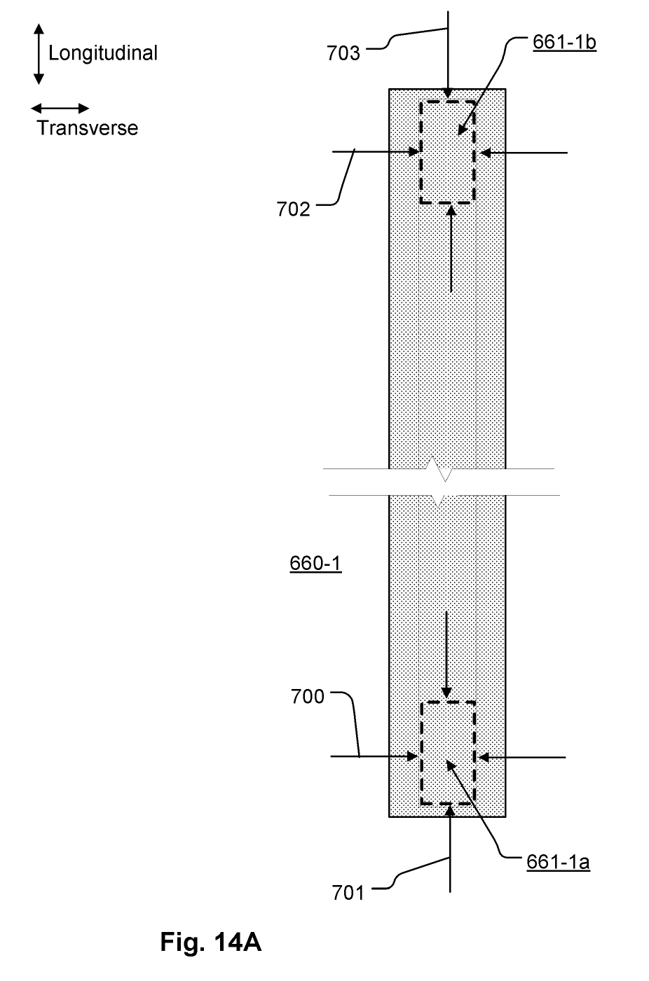

FIG. 12 shows a layout view of a level in an alternate embodiment, showing left side and right side conductors 110-112 from the top level of FIG. 4 and an extra right side conductor 155, with extensions 150, 151 for connection of the left side and right side conductors (110, 111, 112 and 155) to the left and right plane decoders. The reference numerals used in FIG. 4 are repeated in FIG. 12 where appropriate. As can be seen, the left side conductors 110, 112 are coupled to an extension 151 which is adapted for connection to a contact plug on a landing area 153, through which connection to a decoder circuit on the integrated circuit substrate can be made. Likewise, right side conductors 155, 111 are coupled to an extension 150 which is adapted for connection to a contact plug on landing area 152, through which connection to a decoder circuit on the integrated circuit substrate can be made.

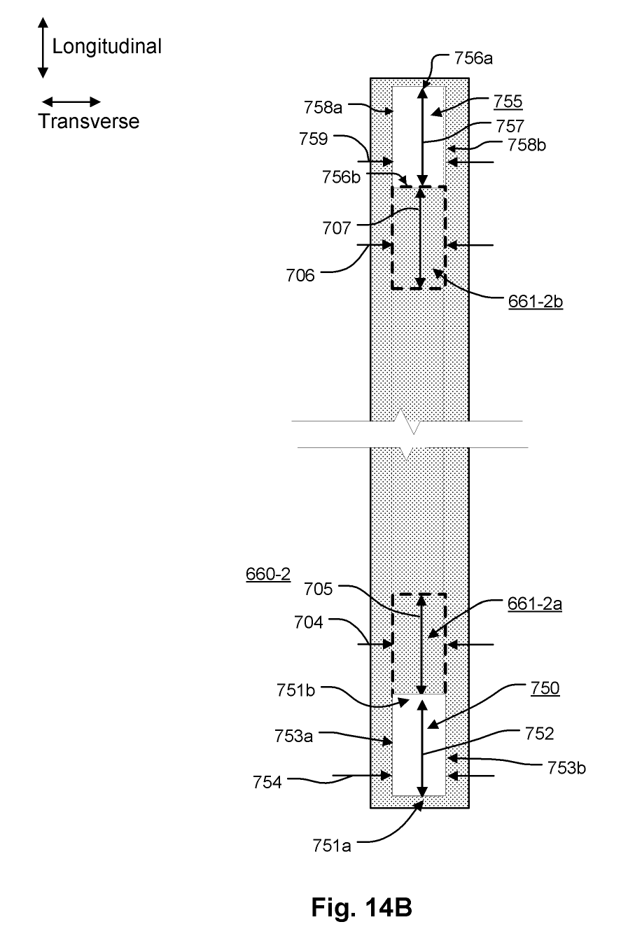

FIG. 13 is a cross-sectional view of the interconnect structure taken through conductor lines 660-1, 660-2 and 660-3 of FIG. 11, where conductors 680-1, 680-2, 680-3 extend through vias to landing areas on the right side conductors 660-1 to 660-3 in respective levels. In the illustrated example three levels of conductor lines 660-1 to 660-3 are shown. The conductors 680-1, 680-2, 680-3 are used in this example for coupling the levels to interconnect lines (e.g. line 685) in a wiring layer, such as a patterned metallization layer for connection to decoding or bias circuits.

The landing areas are portions of patterned conductors 660-1 to 660-3 used for contact with conductors 680-1, 680-2, 680-3. The sizes of the landing areas are large enough to provide room for the conductors 680-1, 680-2, 680-3 to adequately couple the conductors 660-1 to 660-3 on the various levels to the overlying interconnect lines (e.g., 685), as well as to address issues such as alignment tolerances.

The size of a landing area thus depends on a number of factors, including the size and number of conductors used, and will vary from embodiment to embodiment.

For the purpose of this description, the direction in which the patterned conductors 660-1 to 660-3 extend is referred to herein as the “longitudinal” direction. The “transverse” direction is perpendicular to the longitudinal direction, and is into and out of the cross-section illustrated in FIG. 13. Both the longitudinal and transverse directions are considered to be “lateral dimensions,” meaning a direction that is in a 2-dimensional area of a plan view of the conductors 660-1 to 660-3 on the various levels. The “length” of structures or features is its length in the longitudinal direction, and its “width” is its width in the transverse direction.

Conductor line 660-1 is the lowest level in the plurality of levels. The conductor line 660-1 includes landing area 661-1. The conductor line 660-2 includes landing area 661-2. The conductor line 660-3 includes landing area 661-3.

In FIG. 13, the right side conductor line 660-1 includes landing area 661-1 on the right end. Left side conductor lines, such as line 861-1 in FIG. 12, include landing areas on the left end. In some alternative embodiments additional landing areas may be defined, such as a landing area on the opposite end of the conductor line. This structure can be made using a first mask to define a longitudinal opening over the left side and right side conductors, and a second mask to define an opening over a landing area to the lowest layer through all the overlying layers, etching the opening, and then trimming the mask to define a next opening, etching the opening, and trimming the mask and so on until openings to all the layers are formed, and landing areas are created in a stair-step configuration, that are aligned on the conductor lines, and that are not overlaid by conductor lines on any overlying layer. A more detailed description of a process for manufacturing this structure is shown in my co-pending U.S. patent application entitled 3D INTEGRATED CIRCUIT LAYER INTERCONNECT, application Ser. No. 12/579,192, filed 14 Oct. 2009, which is incorporated by reference as if fully set forth herein.

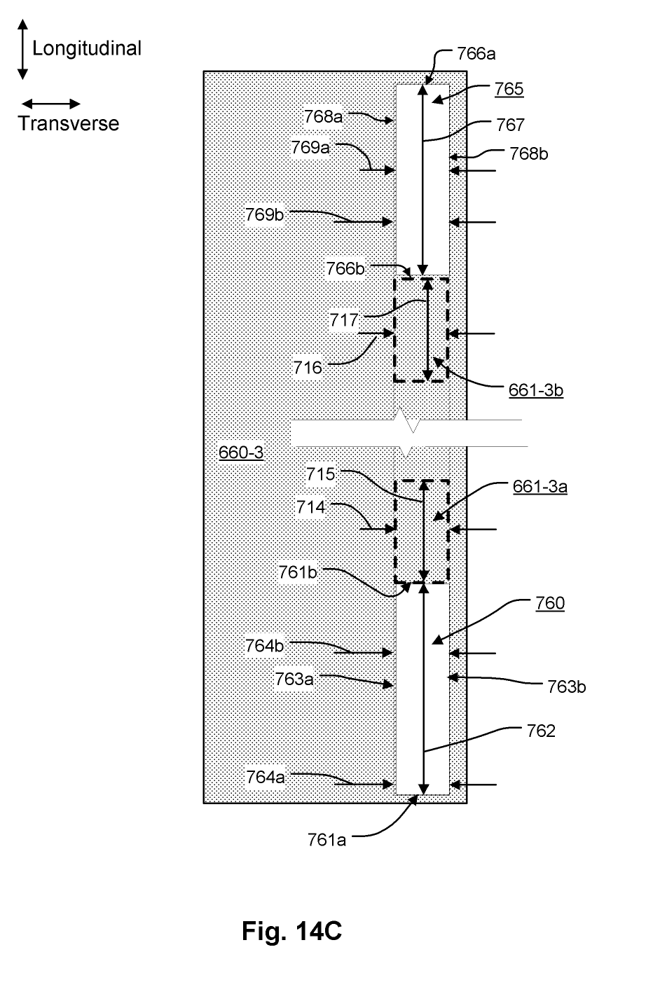

FIG. 14A is a plan view of a portion of conductor line 660-1, including the landing areas 661-1a, 661-1b, one on each end of the conductor line, so that all the left side and right side conductors can be formed in the same process. The width of the conductor line 660-1 in this drawing is exaggerated for the purpose of clarity in the figure. As shown in FIG. 14A, landing area 661-1a has a width 700 in the transverse direction and a length 701 in the longitudinal direction. Landing area 661-1b has a width 702 in the transverse direction and a length 703 in the longitudinal direction. In the embodiment of FIG. 14A the landing areas 661-1a, 661-1b each have a rectangular cross-section. In embodiments, the landing areas 661-1a, 661-1b may each have a cross-section that is circular, elliptical, square, rectangular, or somewhat irregularly shaped.

Because conductor line 660-1 is in the lowest level, the vertical conductors (like conductors 680-1, 680-2, 680-3) in the vias need not pass through the conductor line 660-1 to underlying levels. Thus, in this example conductor line 660-1 does not have openings.

FIG. 14B is a plan view of conductor line 660-2. As illustrated in FIG. 13, conductor line 660-2 overlies conductor line 660-1. Conductor line 660-2 includes an opening 750 overlying the landing area 661-1a on conductor line 660-1. The opening 750 has a distal longitudinal sidewall 751a and a proximal longitudinal sidewall 751b defining the length 752 of the opening 750. The length 752 of the opening 750 is at least as large as the length 705 of the underlying landing area 661-1a, so that the conductor 680-1 for the landing area 661-1a can pass through the conductor line 660-2.

The conductor line 660-2 also includes opening 755 overlying the landing area 661-1b. The opening 755 has distal and proximal longitudinal sidewalls 756a, 756b defining the length 757 of the opening 755. The length 757 of the opening 755 is at least as large as the length 707 of the underlying landing area 661-1b, so that the conductors for the landing area 661-1b can pass through the conductor line 660-2.

The conductor line 660-2 also includes first and second landing areas 661-2a, 661-2b adjacent the openings 750, 755 respectively. The first and second landing areas 661-2a, 661-2b are the portions of conductor line 660-2 used for contact with the vertical conductors.

FIG. 14C is a plan view of a portion of conductor line 660-3, including the first and second landing areas 661-3a, 661-3b and the openings 760, 765 within the interconnect structure. As shown in FIG. 14C, conductor line 660-3 includes an opening 760, which is arranged to overlie landing area 661-1a on conductor line 660-1 and landing area 661-2a on conductor line 660-2. The opening 760 has distal and proximal longitudinal sidewalls 761a, 761b defining the length 762 of the opening 760. The length 762 of the opening 760 is at least as large as the sum of the lengths 701 and 705 of the underlying landing areas 661-1a and 661-2a, so that the conductors 680 for the landing areas 661-1a and 661-2a can pass through the conductor line 660-3.

The distal longitudinal sidewall 761a of opening 760 is vertically aligned with the distal longitudinal sidewall 751a of the underlying opening 750. As mentioned above, the openings can be formed using the opening in a single etch mask and one additional mask formed over the opening in the single etch mask, as well as processes for etching the additional mask without a critical alignment step, resulting in the formation of openings having distal longitudinal sidewalls (761a, 751a, . . . ) along the perimeter of the single etch mask that are vertically aligned.

The conductor line 660-3 also includes opening 765 overlying the landing area 661-1b on conductor line 660-1 and landing area 661-2b on conductor line 660-2. The opening 765 has outside and inside longitudinal sidewalls 766a, 766b defining the length 767 of the opening 765. The outside longitudinal sidewall 766a of opening 765 is vertically aligned with the outside longitudinal sidewall 756a of the underlying opening 755.

The length 767 of the opening 765 is at least as large as the sum of the lengths of the underlying landing areas and openings, so that the conductors 680 for the landing areas can pass through.

The conductor line 660-3 also includes first and second landing areas 661-3a, 661-3b adjacent the openings 760, 765 respectively. The first and second landing areas 661-3a, 661-3b are the portions of conductor line 660-3 used for contact with the conductors 680. As shown in FIG. 14C, landing area 661-3a is adjacent the opening 760 and has a width 714 in the transverse direction and a length 715 in the longitudinal direction. Landing area 661-3b is adjacent the opening 765 having a width 716 in the transverse direction and a length 717 in the longitudinal direction.

In the illustrated embodiment, the openings in the various conductor lines 660-1 to 660-3 have substantially the same width in the transverse direction. Alternatively, the width of the openings can vary along the longitudinal direction, for example in a step-like manner, in order to accommodate landing areas having different widths.

In the cross-section of FIG. 13, the openings within the interconnect structure result in the levels having a staircase-like pattern on both ends. That is, the two openings in each level are symmetrical about an axis perpendicular to both the longitudinal and transverse directions, and the two landing areas of each level are also symmetrical about that axis. As used herein, the term “symmetrical” is intended to accommodate manufacturing tolerances in the formation of the openings using the opening in a single etch mask and multiple etch processes which may cause variations in the dimensions of the openings.

In alternative embodiments in which each level includes a single opening and a single landing area, the levels have a staircase-like pattern on only one side.

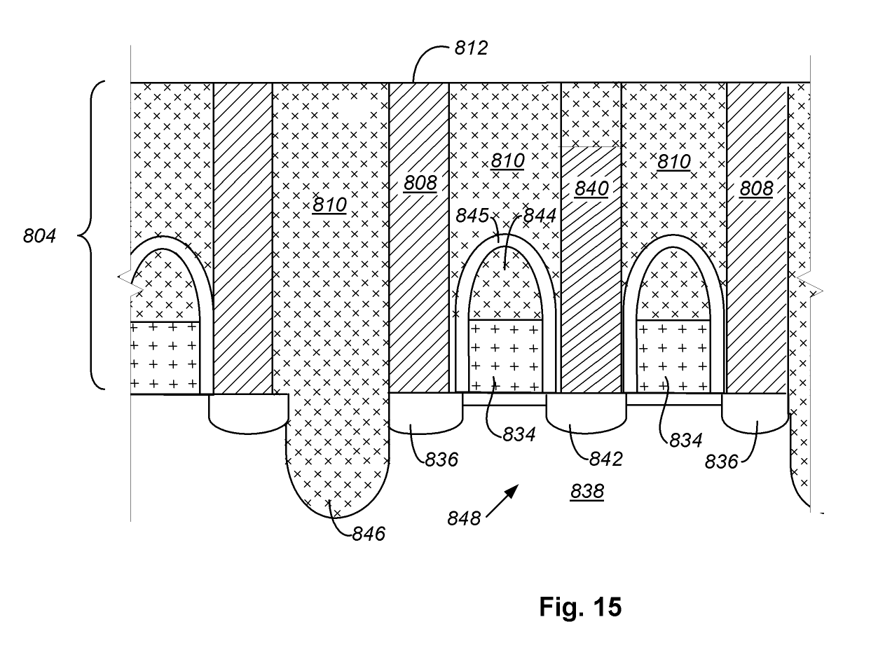

FIG. 15 shows one example implementation for an array of access devices suitable for use as the pillar access device array shown in FIG. 1. As shown in FIG. 15, an access layer 804 is implemented in a substrate including insulating material 810, having a top surface with an array of contacts (e.g. contact 812) exposed thereon. The contacts for individual pillars are provided at top surfaces of drain contacts 808, which are coupled to the drain terminals of MOS transistors in the access layer. The access layer 804 includes a semiconductor body having source regions 842 and drain regions 836 therein. Polysilicon word lines 834 are provided over gate dielectric layers and between the source regions 842 and drain regions 836. In the embodiment shown, the source regions 842 are shared by adjacent MOS transistors, making two-transistor structures 848. Source contacts 840 are positioned between word lines 834 and contact source regions 842 within substrate 838. The source contacts 840 can be connected to bit lines (not shown) in a metal layer, which run perpendicular to the word lines and between the columns of drain contacts 808. Word lines 834 are covered by silicide caps 844. Word lines 834 and caps 844 are covered by a dielectric layer 845. Isolation trenches 846 separate the two-transistor structures 848 from the adjacent two-transistor structures. In this example transistors act as the access devices. Individual pillars can be coupled to the contacts 812, and selected individually by controlling the biasing of the source contacts 840 and the word lines 834. Of course other structures may be used to implement the access device array, including for example, vertical MOS device arrays.

FIG. 16 is a simplified block diagram of an integrated circuit according to an embodiment of the present invention. The integrated circuit line 975 includes a 3D two-cell unit structure, anti-fuse memory array 960, implemented as described herein, on a semiconductor substrate. Addresses are supplied on bus 965 to column decoder 963, row decoder 961 and left/right plane decoder 958. An array of access devices for individual pillars underlies the array 960, and is coupled to the row decoder 961 and the column decoder 963, for array embodiments like that shown in FIG. 1. Sense amplifiers and data-in structures in block 966 are coupled to the array in this example via data bus 967. Data is supplied via the data-in line 971 from input/output ports on the integrated circuit 975 or from other data sources internal or external to the integrated circuit 975, to the data-in structures in block 966. In the illustrated embodiment, other circuitry 974 is included on the integrated circuit, such as a general purpose processor or special purpose application circuitry, or a combination of modules providing system-on-a-chip functionality supported by the memory cell array. Data is supplied via the data-out line 972 from the sense amplifiers in block 966 to input/output ports on the integrated circuit 975, or to other data destinations internal or external to the integrated circuit 975.

A controller implemented in this example using bias arrangement state machine 969 controls the application of bias arrangement supply voltages generated or provided through the voltage supply or supplies in block 968, such as read and program voltages. The controller can be implemented using special-purpose logic circuitry as known in the art. In alternative embodiments, the controller comprises a general-purpose processor, which may be implemented on the same integrated circuit, which executes a computer program to control the operations of the device. In yet other embodiments, a combination of special-purpose logic circuitry and a general-purpose processor may be utilized for implementation of the controller.

Three-dimensional stacking is an efficient way to reduce the cost per bit for semiconductor memory, particularly when physical limitations in the size of the memory elements is reached for a given plane. Prior art technology addressed to 3D arrays requires several critical lithography steps to make minimum feature size elements in each stack layer. Also, driver transistors used for the memory array multiplied in number by the number of planes.

Technology described here includes a high density 3D array in which only one critical layer lithography step is required to pattern all the layers. The memory via and layer interconnect via patterning steps shared by each layer. Also, the layers can share the word line and bit line decoders to reduce the area penalty of prior art multilevel structures. Also, a unique 2-cell unit structure is described for anti-fuse or other programmable resistance memory in which data sites are provided on each of two sides of a memory pillar. An array of access devices is used to select individual memory pillars. Left and right word lines are used to select individual cells on selected planes.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
an array of access devices;
a plurality of patterned conductor layers, separated from each other and from the array of access devices by insulating layers, the plurality of patterned conductor layers including left side and right side conductors;
an array of conductive pillars extending through the plurality of patterned conductor layers, the conductive pillars in the array contacting corresponding access devices in the array of access devices, and defining left side and right side interface regions between the conductive pillars and adjacent left side and right side conductors in corresponding patterned conductor layers in the plurality of patterned conductor layers; and
memory elements in the left side and right side interface regions, each of said memory elements comprising a programmable element.

2. The memory device of claim 1, including
row decoding circuits and column decoding circuits coupled to the array of access devices arranged to select a conductive pillar in the array of conductive pillars; and
left and right plane decoding circuits coupled to the left side and right side conductors in the plurality of patterned conductor layers arranged to forward bias the rectifiers in a selected cell in a left side or right side interface region in a selected patterned conductor layer and to reverse bias the rectifier in an unselected cell.

3. The memory device of claim 1, wherein a conductive pillar in the array of conductive pillars comprises a conductor in electrical communication with a corresponding access device, and a layer of memory material between the conductor and the plurality of patterned conductor layers, wherein the programmable element in each of said memory elements comprises an active region in the layer of memory material at the interface regions.

4. The memory device of claim 1, wherein an access device in the array of access devices comprises:
a transistor having a gate, a first terminal and a second terminal; and
the array including a bit line coupled to the first terminal, a word line coupled to the gate, and wherein the second terminal is coupled to a corresponding conductive pillar in the array of conductive pillars.

5. The memory device of claim 1, wherein an access device in the array of access devices comprises a vertical transistor having a first source/drain terminal coupled to a corresponding conductive pillar in the array of conductive pillars; and
the array including a source line or bit line coupled to source/drain terminal of the vertical transistor, and a word line providing a surrounding gate structure.

6. The memory device of claim 1, wherein a conductive pillar in the array of conductive pillars comprises a semiconductor material having a first conductivity type;
and the left side and right side conductors in the plurality of patterned conductor layers comprise doped semiconductor material having a second conductivity type, so that the rectifier in each of said memory elements comprises a p-n junction.

7. The memory device of claim 1, wherein the left side and right side conductors in the plurality of patterned conductor layers are configured for contact to corresponding left side and right side plane decoding circuitry.

8. The memory device of claim 1, wherein the array of access devices underlie the plurality of patterned conductor layers.

9. The memory device of claim 1, wherein the left side and right side conductors in each layer have landing areas that are not overlaid by any of the left side and right side conductors in overlying patterned conductor layers; and including conductive lines extending through the plurality of conductor layers and contacting the landing areas; and left side and right side connectors over the plurality of patterned conductor layers and in contact with the conductive lines; and
left and right plane decoding circuits coupled to the left side and right side connectors.

10. A method for manufacturing a memory device, comprising:
forming an array of access devices;
forming a plurality of patterned conductor layers, separated from each other and from the array of access devices by insulating layers, the plurality of patterned conductor layers including left side and right side conductors;
forming an array of conductive pillars extending through the plurality of patterned conductor layers, the conductive pillars in the array contacting corresponding access devices in the array of access devices, and defining left side and right side interface regions between the conductive pillars and the left side and right side conductors in corresponding patterned conductor layers in the plurality of patterned conductor layers; and
forming memory elements in the left side and right side interface regions, each of said memory elements comprising a programmable element.

11. The method of claim 10, wherein said forming a plurality of patterned conductor layers includes:
forming a plurality of blanket layers of conductive material;
forming blanket layers of insulating material between the blanket layers of conductive material to form a stack; and
etching the stack including the plurality of blanket layers to define the left side and right side conductors.

12. The method of claim 11, wherein said etching the stack includes etching trenches through the plurality of patterned conductor layers, and said forming an array of conductive pillars includes:
depositing a memory material on sidewalls of the trenches;
filling the trenches over the memory material on the sidewalls with an electrode material; and
patterning the electrode material within the trenches to form the array of conductive pillars.

13. The method of claim 12, wherein said electrode material comprises a doped semiconductor, and the plurality of patterned conductor layers comprise doped semiconductor material of opposite conductivity type, defining a p-n junction in the interface regions.

14. The method of claim 10, wherein the programmable element comprises an anti-fuse.

15. The method of claim 10, including patterning the plurality of patterned conductor layers so that the left side and right side conductors in each layer have landing areas that are not overlaid by any of the left side and right side conductors in overlying patterned conductor layers; forming vias exposing the landing areas; forming conductive lines in the vias; and forming connectors over the plurality of patterned conductor layers and in contact with the conductive lines in the vias, the connectors adapted for connection to decoding circuitry.

16. A memory device, comprising:
an array of access devices;
a conductive plug substantially vertical and electrically coupled to the array of access devices;
first and second conductive lines crossover the conductive plug and over the array of access devices;
a first memory element between the first conductive line and the conductive plug; and
a second memory element between the second conductive line and the conductive plug, wherein the first memory cell is over the second memory cell.
